(19) United States
(12) Patent Application Publication
(10) Pub. No.: US 2004/0101148 A1
(43) Pub. Date: May 27, 2004

(54) Electronic appliance audio filtering based on output device selection

(76) Inventors: Norman C. Pyle, Greeley, CO (US); Mark J. Bianchi, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/304,658

(22) Filed: Nov. 25, 2002

(51) Int. Cl. H03G 5/00

(52) U.S. Cl. 381/101

(57) ABSTRACT

Audio produced by an electronic appliance is selectively filtered based upon the output device selected. The destination of the audio signal is detected and filtering of the audio signal is configured based on the destination. If the frequency response of the output device is narrow, such as with an internal speaker in the electronic appliance, a bandpass filter is applied to narrow the frequency range of the audio signal to match the frequency response of the output device.

### Background

There are many popular appliances that play audio, such as digital cameras, portable audio players, and personal digital assistants (PDAs). Each of these appliances may be designed to play the audio on more than one output device, such as on an internal speaker in the appliance or on external devices connected to the appliance, including headphones, a stereo, television, or computer, etc. Each of these audio output devices has different properties, capabilities, and limitations. For example, the power required to drive an internal speaker is higher than that required by an external stereo, because the external stereo amplifies the audio signal itself. Other differences between audio output devices include their frequency response, or the range of frequencies the devices are capable of reproducing, and their distortion levels at various frequencies. For example, small inexpensive internal speakers in many electronic appliances, particularly portable appliances, may significantly distort low frequencies and may be unable to reproduce very high and very low frequencies, so power used to amplify these high and low frequencies is wasted when the audio is sent to an internal speaker.

Some electronic appliances include a mechanism for detecting whether an internal or external output device is receiving the audio signal. This mechanism is often part of the output audio jack in the appliance, producing a signal indicating that a cable is plugged into the jack. Electronic appliances can monitor the signal and reduce the power of the audio signal when it is being sent to an external self-amplified output device, reducing the power usage in the appliance.

However, electronic appliances that are designed to provide an audio output tailored to the properties of an external device generally produce poor sound from the internal speaker. The small inexpensive speakers included in many electronic appliances may distort low and high frequencies at the edges of their frequency response. Perhaps more importantly, low frequency audio signals may cause these speakers to distort the sound in the more important mid-range frequencies. Thus, electronic appliances are often tailored to an external audio output device at the expense of the internal speaker output quality, or balances are struck providing mediocre sound from both internal or external output devices.

### SUMMARY

Audio quality produced by an electronic appliance is greatly improved by selectively filtering the audio signal in the electronic appliance based on the properties of the output device. An audio filter may be applied to the audio signal based on the properties of the output device. For example, if the output device is a small inexpensive speaker, the audio signal may be filtered with a bandpass filter tailored to the frequency response of the speaker before it is amplified. This reduces wasted power and prevents distortion of the sound produced by the speaker. If the output device is an external device, a filter tailored to the frequency response of the external device may be applied. Alternatively, the audio signal may be sent to the external device without filtering, sending the entire frequency range of the audio signal to the external device. The audio signal may be filtered with any suitable filter, such as a hardware-based analog filter or a hardware or firmware-based digital filter.

In one exemplary embodiment, a filter is permanently connected in series with an output device so that any audio signal to the output device is filtered appropriately.

In another exemplary embodiment, a mechanism in the electronic appliance detects what output device is receiving the audio signal, such as an internal speaker or an external self-amplified output device, and a switch routes the audio signal through the appropriate filter before the audio signal reaches the output device.

### BRIEF DESCRIPTION OF THE DRAWING

Illustrative embodiments of the invention are shown in the accompanying drawing, in which:

FIG. 1 is an illustration of an exemplary embodiment of a digital camera having an audio output connected to a television;

FIG. 2 is an illustration of an exemplary embodiment of a video camera having an audio output connected to a television;

FIG. 3 is an illustration of an exemplary embodiment of a personal digital assistant having an audio output connected to headphones;

FIG. 4 is a block diagram of an exemplary digital camera adapted for audio filtering based on output device selection;

FIG. 5 is a block diagram of an exemplary audio system for audio filtering based on output device selection;

FIG. 6 is a block diagram of an alternative exemplary audio system for audio filtering based on output device selection;

FIG. 7 is an illustration of an exemplary highpass filter;

FIG. 8 is an illustration of an exemplary lowpass filter;

FIG. 9 is an illustration of an exemplary bandpass filter;

FIG. 10 is an illustration of an exemplary bandpass filter and amplifier with switchable frequency response;

FIG. 11 is a graph showing the idealized frequency response of an exemplary small speaker;

FIG. 12 is a graph showing the frequency range of an exemplary audio signal from an exemplary audio processor in an electronic appliance;

FIG. 13 is a graph showing the frequency output of an exemplary filter and exemplary audio power amplifier that may be used in an electronic appliance sending audio to an external output device;

FIG. 14 is a graph showing the frequency output of an exemplary filter that may be used in an electronic appliance sending audio to an exemplary small speaker; and

FIG. 15 is a flowchart summarizing an exemplary operation for filtering audio in an electronic appliance based on output device selection.

### DESCRIPTION

The drawing and description, in general, disclose audio filtering in an electronic appliance based on audio output device selection. The audio signal from the electronic appliance may be matched in frequency range as well as power to the output device, maximizing efficient power use and minimizing distortion. The best possible audio signal may thus be produced by each of the output devices available to the electronic appliance.

The term “electronic appliance” refers to any electronic device that generates an audio signal and has more than one audio output device. Some examples of electronic appliances are digital cameras, video cameras, personal digital assistants (PDAs), portable audio players including cassette, cd, and mp3 players, etc.

Audio that may be produced and filtered by an electronic appliance may include any sound, generally in electronic form, from an electronic appliance. In a digital camera, the audio may be a soundtrack recorded by the camera while capturing images or video clips. In a PDA, the audio may be music, beeps or chimes produced by an operating system, a soundtrack to a video played on the PDA, etc. Typical electronic appliances produce audio signals with a frequency range of about 10 hertz (Hz) to about 20 kilohertz (kHz), but selective audio filtering in an electronic appliance is not limited to use with any particular type or form of audio signal or any particular range of frequencies.

The audio output devices are not limited to any particular type of output but may include internal speakers in the electronic appliance, output jacks or wireless transmitters to external devices, sound file transfers to personal computers via network, disk, or any other means, etc. Output jacks include devices such as headphone jacks, line out jacks, digital input/output (I/O) jacks, etc. External devices include such devices as televisions, stereos, computers, speakers, etc., and may or may not be self-amplified.

The output devices available to the electronic appliance may have a wide range of audio specifications, such as how well they are able to reproduce various frequencies in an audio signal without distortion. The term distortion is used herein to refer to any departure of the output audio waveform from that which should result from the input audio waveform. This includes distortion caused by the electrical or physical characteristics of the output device or the transmission medium used to propagate the audio signal to the output device.

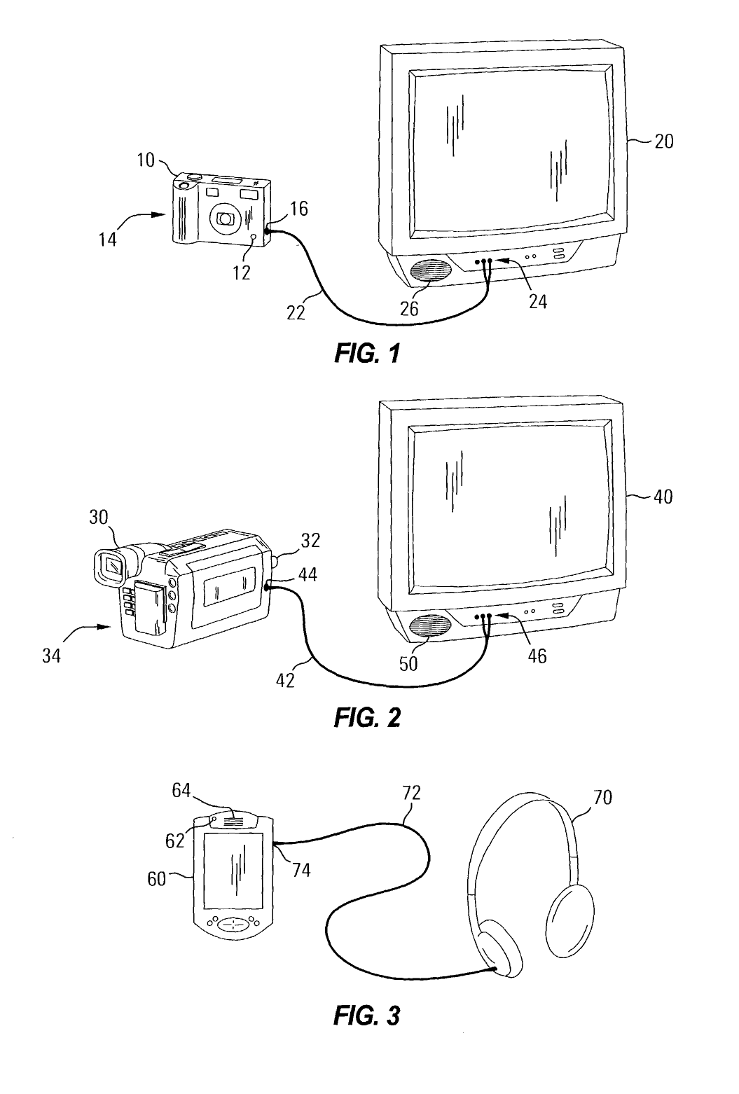

Some examples of electronic appliances and their associated output devices are illustrated in FIGS. 1-3. In these examples, the electronic appliances are portable with internal speakers having particularly limited frequency responses. However, audio filtering based on output device selection is not limited to any particular type of electronic appliance such as portable appliances, and is not limited to electronic appliances having internal output devices like internal speakers.

A digital camera 10 is shown in FIG. 1. The digital camera 10 is adapted for capturing audio along with pictures or video clips. A microphone 12 is used to capture the audio, and it is stored in the digital camera 10 along with images or video clips. The digital camera 10 contains a small speaker 14 (not shown) for playing back the audio while previewing pictures or video clips. The digital camera 10 also contains an output jack 16 for connecting the digital camera 10 to a television 20. A cable 22 is plugged into the digital camera output jack 16 and audio input jacks 24 on the television 20. (A video connection between the digital camera 10 and television 20 is not shown.) With the digital camera 10 connected to the television 20, an audio signal from the digital camera 10 travels to the television 20 along the cable 22, may be amplified in the television 20, and is played on one or more speakers 26 in the television 20.

Because the internal speaker 14 in the digital camera 10 is extremely small and is chosen in part for its low cost, its frequency response is much narrower and more restricted than that of the television speaker 26. This results in a distorted signal if an audio signal with a wide frequency range is played back on the internal speaker 14. If, however, the audio signal from the digital camera 10 is either filtered to have a narrow frequency range or is originally captured by the microphone 12 with a narrow frequency range, the audio will sound somewhat tinny and shallow when played back on the television speaker 26. By capturing the audio signal with a wide frequency range in the digital camera 10, then filtering the audio signal according to the frequency response and other characteristics of the selected output device (e.g., 14 or 26), the highest possible sound quality will be produced on any available output device (e.g., 14 or 26).

The electronic appliance may also consist of a video camera 30, as shown in FIG. 2. A microphone 32 is used to capture audio in the video camera 30, which may be played back on an internal speaker 34 (not shown). As with the digital camera 10, the frequency response of the internal speaker 34 in the video camera 30 is relatively limited and prone to distortion when an audio signal having a wide frequency range is played.

The video camera 30 may also be connected to a television 40 by a cable 42 attached to jacks 44 and 46 in the video camera 30 and television 40, respectively. As with the digital camera 10 described above, the audio signal from the video camera 30 may be amplified in the television 40 and played back on a speaker 50 in the television 40. Again, the speaker 50 in the television 40 generally has a wider frequency response than the internal speaker 34 in the video camera 30, as it is larger and is typically a more expensive and higher quality speaker, being required to play high quality audio for television programs and movies.

Selective audio filtering in the video camera 30 allows the same audio signal to be tailored to the frequency response of the internal speaker 34 in the video camera 30 or the speaker 50 in the television 40, providing the best possible sound quality on either output device.

Another exemplary electronic appliance is a PDA 60. Audio files may be transferred to the PDA 60 from a personal computer or other PDAs, or may be captured by an internal microphone 62, or may be internally generated by the operating system or applications on the PDA. The audio files in the PDA 60 may be played back on an internal speaker 64, or on headphones 70 connected to the PDA 60 by a cable 72 plugged into a headphone jack 74. Again, the frequency response of the internal speaker 64 is likely much more limited than that of the headphones 70, so playing the same audio signal on either will result in less than optimal sound on one or both.

Selective audio filtering in the PDA 60 allows the audio signal to be tailored to the selected output device, whether the internal speaker 64 or the headphones 70.

As will be described in more detail below, the electronic appliance detects which of several available output devices is currently selected, and filters the audio signal accordingly. This selective filtering may be accomplished in any suitable manner. For example, a switch in the electronic appliance may direct the audio signal through a hardware filter matching the properties of the currently selected output device. If the entire frequency range in the audio signal fits within the frequency response of the currently selected output device without distortion, the audio signal may be switched directly to the output device, bypassing any filters in the electronic appliance. If the electronic appliance uses software filters on the audio signal, the software filters may be configured according to the properties of the currently selected output device.

Detection of the currently selected output device may also be performed in any suitable manner. For example, output jacks in the electronic appliance may provide a signal indicating whether a cable is plugged into the jack. In a typical electronic appliance, the properties of external devices that may be plugged into output jacks are known in advance, such as a self-amplified television 20 as a suitable external device for a digital camera 10. For this exemplary case, in which the audio signal is played on a self-amplified television speaker 26 with a wide frequency response, filtering in the digital camera 10 may be unnecessary, and indeed, undesirable. Thus, when a cable is plugged into the jack 16 designated for a television connection in the digital camera 10, filters in the digital camera 10 may be bypassed by the audio signal.

Alternatively, appropriate filters may be permanently mounted in series with the corresponding output devices, so that any audio signal traveling to an output device is suitably filtered. In this exemplary embodiment, the electronic appliance may drive multiple audio outputs simultaneously, each with an audio signal containing the appropriate frequency range.

Audio filtering in an electronic appliance based on output device selection provides great benefits at low cost. The quality of the sound produced by the electronic appliance may be dramatically improved by matching the frequency range in the audio signal to the distortion-free frequency response of the output device. The electronic appliance can thus produce the best possible sound quality on every type of output device, from a very small inexpensive internal speaker to external self-amplified stereo systems. Power may also be efficiently used by filtering out frequency components of the audio signal which cannot be reproduced by the selected output device, particularly when the audio signal is filtered before amplification.

Audio filtering based on output device selection may be employed with any type of electronic appliance. Although selective audio filtering is described herein with respect to particular portable appliances such as a digital camera 10, it is important to note that it is not limited to use with any particular type of electronic appliance. It may be used with any device, portable or not, whose internal speaker system has been optimized for cost, space or other parameters at the expense of frequency response, or with other devices with output devices (even if all are external) having different frequency responses. Before describing audio filtering based on output device selection, an exemplary digital camera 10 which may be adapted for selective audio filtering will be described in more detail.

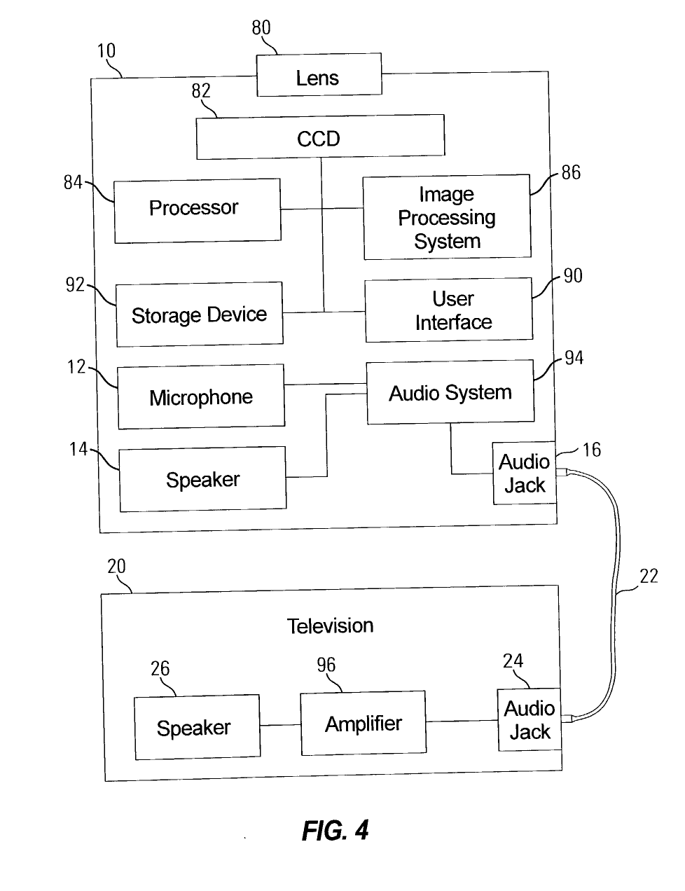

Referring now to FIG. 4, an exemplary digital camera 10 comprises a lens 80 which focuses image light onto a photodetector such as a charge-coupled device (CCD) 82. A processor 84 controls the digital camera 10, including components such as an image processing system 86 and a user interface 90. The image processing system 86 receives the image data generated by the CCD 82, formatting the image data as needed. The user interface 90 provides and processes menus, button input, etc. Images and other data such as sound files may be stored in a storage device 92 in the digital camera 10.

An audio system 94 in the digital camera 10 controls any audio functions, such as recording sound clips through a microphone 12, playing back sound clips through an internal speaker 14, and sending an audio signal to external devices through an audio jack 16. The audio system 94 may comprise any suitable device in the digital camera 10 for performing the necessary functions. For example, the audio system 94 may comprise one or more general purpose processors, one or more application specific integrated circuits (ASICs) or other task-specific processors, standalone signal processors, etc. As will be described in more detail below, the audio system 94 may also include filters, amplifiers, switches, and other components as needed to provide and filter an audio signal based on output device selection. For example, the audio signal may be played on a television 20 connected to the digital camera 10, and the audio system 94 may include components for filtering the audio signal according to the properties of the television 20. The audio signal is sent to the television 20 through a cable 22 connected to audio jacks 16 and 24 in the digital camera 10 and television 20, respectively. The audio signal may be amplified in the television 20 in an amplifier 96, then reproduced by the television speaker 26.

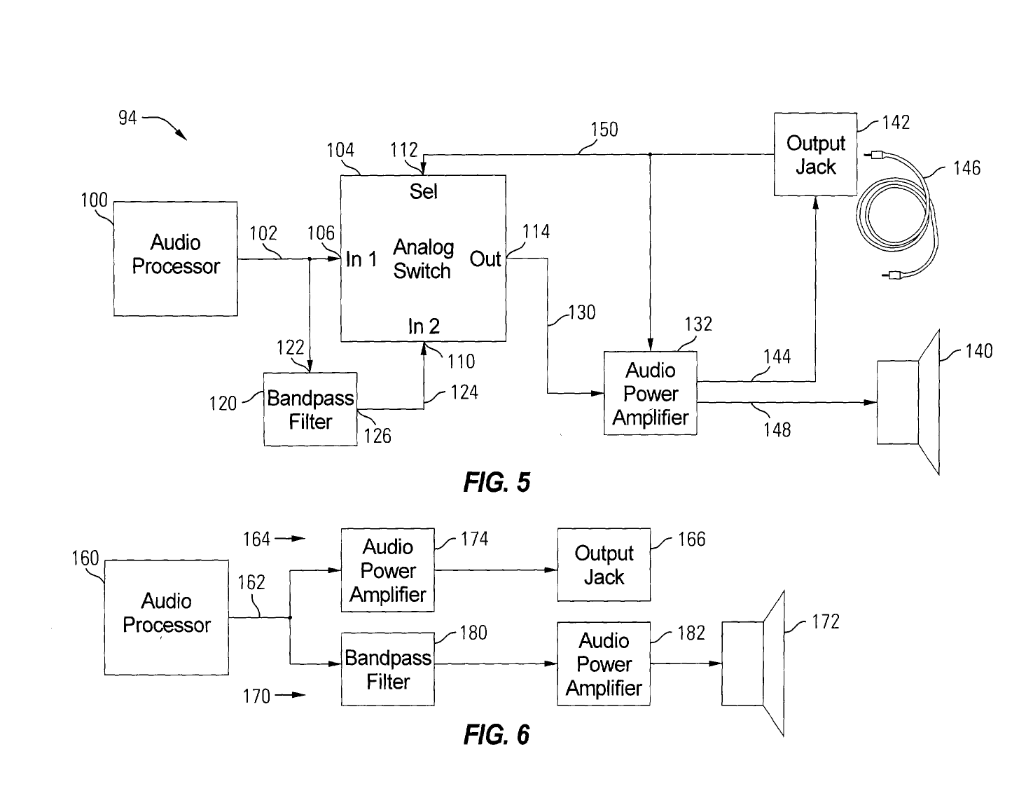

One exemplary embodiment of an audio system 94 suitable for selective audio filtering in an electronic appliance is illustrated in FIG. 5. In this audio system 94, a hardware-based filter is employed. An audio processor 100 provides an audio signal 102 having a frequency range wide enough for a quality sound in the best available output device.

The term “frequency range” refers herein to the range of frequencies predominantly present in an audio signal. For the purposes of this discussion, a filtered audio signal in which frequencies less than 200 Hz are attenuated has a different frequency range than the original unfiltered audio signal, even if there is some signal remaining at frequencies less than 200 Hz. The fact that they have been attenuated in a filter results in a signal having a different “frequency range” than the original signal.

An analog switch 104 is provided having two inputs 106 and 110, although more inputs may be provided depending on the number of available output devices. A switch selector 112 controls which of the two inputs 106 and 110 is connected to an output 114 on the switch 104.

A filter 120 is also provided in the audio system 94. In the exemplary embodiment, the filter 120 is a bandpass filter with knees positioned according to the distortion properties and frequency response of a corresponding output device, as will be described below. The audio signal 102 from the audio processor 100 is connected to an input 122 on the bandpass filter 120, resulting in a filtered audio signal 124 on an output 126 of the bandpass filter 120. The frequency range of the filtered audio signal 124 is narrowed by the bandpass filter 120 according to the frequency response of the corresponding output device, or the frequencies which can be reproduced without distortion by the corresponding output device.

The unfiltered audio signal 102 from the audio processor 100 is connected to the first switch input 106, and the filtered audio signal 124 from the bandpass filter 120 is connected to the second switch input 110. Thus, the output 114 of the switch 104 will either be the original unfiltered audio signal 102 or the filtered audio signal 124.

In an alternative embodiment, filters may be desired in the audio system 94 for each available output device. In this case, a filter may be provided for the audio signal before each switch input, rather than just one as in the exemplary embodiment illustrated in FIG. 5.

The switched audio signal 130 produced at the output 114 of the switch 104 may be fed into an audio power amplifier 132 to amplify the switched audio signal 130 as needed according to the requirements of the active output device. The audio signal is filtered by the bandpass filter 120 before amplifying it in the amplifier 132 to avoid wasting power, although the invention is not limited to this configuration. If the audio signal were amplified first, portions of the newly amplified audio signal would then be filtered out. It is generally more efficient to filter the signal first, then to amplify it.

In the present exemplary embodiment, the audio system 94 provides an audio signal to two output devices, an internal speaker 140 and an output jack 142 to an external device such as a television 20. The amplified audio signal 144 from the amplifier 132 is connected to the output jack 142, and also 148 to the internal speaker 140. The audio signal 130 is switched in the audio power amplifier 132 between the output jack 142 and the internal speaker 140, as will be described below. Alternatively, the audio signal 130 may be switched in the output jack 142, or in another analog switch placed at the output of the amplifier 132 to direct the amplified audio signal 144 either to the output jack 142 or to the internal speaker 140.

The output jack 142 produces an output indicator signal 150 indicating whether a cable 146 is plugged into the output jack 142. This output indicator signal 150 identifies which output device (e.g., an external output device or the internal speaker 140) is receiving the amplified audio signal 144. The output indicator signal 150 may be connected to the amplifier 132 to control the level of amplification applied to the switched audio signal 130 and to switch the output between the output jack 142 or the internal speaker 140. The output indicator signal 150 is also connected to the switch selector 112 to control whether the switched audio signal 130 is filtered by the bandpass filter 120. Finally, in the alternative embodiment in which another analog switch is used to direct the amplified audio signal 144 either to the output jack 142 or to the internal speaker 140, the output indicator signal 150 may be used to control this switch.

The audio jack 142 may be replaced by any type of transmission source or any apparatus for disseminating an audio signal from the electronic appliance, including any type of connector, transmitter, network, computer disk, etc. The output indicator signal 150 may be generated by any suitable means for detecting which of the available output devices are active.

In operation, the audio system 94 provides an appropriately filtered and amplified audio signal 144 based on which output device, either the internal speaker 140, or an external device connected to the output jack 142, is receiving the audio signal. If the internal speaker 140 is the current output device, the output jack 142 will detect that a cable is not plugged in, and the output indicator signal 150 will indicate this fact. The switch 104 will therefore select the filtered audio signal 124 from the bandpass filter 120, which has been tailored to the frequency response of the internal speaker 140. The output indicator signal 150 may also cause the amplifier 132 to increase the power of the amplified audio signal 144 to drive the internal speaker 140. The amplified audio signal 144 will travel to the output jack 142 and will be switched back out to the internal speaker 140.

If an external device is the current output device, the output jack 142 will detect that a cable is plugged in, and the output indicator signal 150 will indicate this fact. The switch 104 will therefore select the unfiltered audio signal 102, bypassing the bandpass filter 120. Thus the original audio signal 102, having the widest possible frequency range, will be provided to the external output device. The output indicator signal 150 may also cause the amplifier 132 to decrease the power of the amplified audio signal 144 if the external output device is known to be self-amplified. The amplified audio signal 144 will travel to the output jack 142 and from there to the external output device.

Another exemplary embodiment of an audio system 94 is illustrated in the block diagram of FIG. 6. Depending on the relative complexity, size and cost of the amp and the switch, it may be desirable to use multiple amplifiers and permanently routed filters rather than a switch. This alternative embodiment may also be used when the audio is played back simultaneously on multiple output devices, such as in an internal speaker and on an output jack. This alternative embodiment provides the proper filtering and amplification of the audio signal for each output device simultaneously.

An audio processor 160 provides an audio signal 162 having a frequency range wide enough for quality sound in the best available output device. This audio signal 162 is split into two paths, one 164 leading to an output jack 166 and one 170 leading to an internal speaker 172. The audio may be played simultaneously on multiple output devices, such as on an external device connected to the output jack 166 and on the internal speaker 172. The audio signal 162 is filtered and amplified appropriately based on the output device it is played on. In the first path 164 leading to the output jack 166, an amplifier 174 is used to amplify the audio signal 162 as needed by the external output device. However, no filter is used, as the external output device in this exemplary embodiment is able to reproduce all frequencies present in the audio signal 162 without distortion.

In the second path 170 leading to the internal speaker 172, the audio signal 162 is first filtered in a bandpass filter 180 so that the frequency range of the audio signal may be reproduced by the internal speaker 172 without excessive distortion. After the audio signal 162 has been filtered in the bandpass filter 180, it is amplified as needed in an amplifier 182, then reproduced by the internal speaker 172.

In this exemplary embodiment, the output jack 166 is not used to detect the destination of the audio signal 162. However, the concept of detecting the destination of the audio signal as described herein does apply to this exemplary embodiment, as the routing of the audio signal 162 to the two paths 164 and 170 detects the destination of the audio signal 162. That is, for the audio signal appearing on the path 164 to the output jack 166, the destination is detected as an external device connected to the output jack 166, and filter selection for that destination results in no filtering being performed. For the audio signal appearing on the path 170 to the internal speaker 172, the destination is detected as the internal speaker 172 and the bandpass filter 180 is selected as the filter applied to the audio signal.

The frequency response of the available output devices is generally known in advance, enabling the proper design of the audio system 94 to tailor the frequency range of the audio signal to the frequency response of the output devices. Electronic appliances are often designed for a particular type of external output device, such as a line-in input on a self-amplified stereo or television. The users manual for the electronic appliance often states what type of external output device is suitable for connection to the electronic appliance. For example, the manual for a digital camera may state that the external audio jack on the digital camera is to be connected to the audio line-in input on a television, which is generally capable of reproducing all frequencies in an audio signal without noticeable distortion. Alternatively, if the frequency response or other properties of an external output device are not known in advance, the electronic appliance may be configurable to adjust the filters in the audio system 94, particularly if software filters are employed.

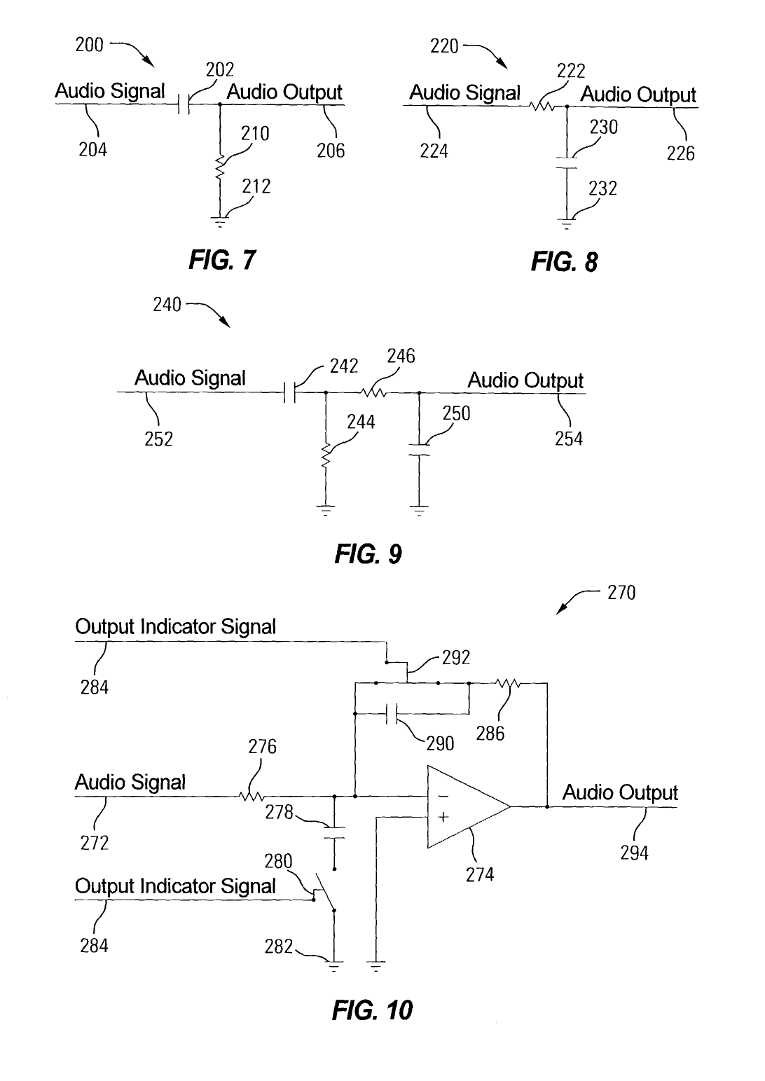

Audio may be selectively filtered in an electronic appliance using any suitable filtering means now known or that may be developed in the future. For example, the filter may be an electronic circuit made of individual logic gates and passive components, or may be implemented in a signal processor, or may be implemented in firmware. Exemplary hardware-based filter circuits are illustrated in FIGS. 7-10. These circuits are extremely simple and may not provide the best audio characteristics, but are included here for discussion purposes. Many higher quality audio filter circuits are well known and may be applied to selectively filter audio in an electronic appliance based on output device selection.

Referring now to FIG. 7, a simple first order highpass filter 200 consists of a capacitor (C) 202 connected in series between the audio input 204 and the audio output 206, with a resistor (R) 210 connected between the output of the capacitor 202 and ground 212. The highpass filter 200 attenuates low frequency components of the audio input 204, passing high frequency components. The cutoff frequency or knee of the highpass filter 200 is calculated as f₀=1/(2*pi*R*C). A capacitor 202 of about 8 microfarads (μF) and a resistor 210 of about 100 kilo-ohms (kΩ) results in a 3 dB cutoff frequency of about 200 Hz, attenuating frequency components below about 200 Hz.

Referring now to FIG. 8, a simple first order lowpass filter 220 consists of a resistor (R) 222 connected in series between the audio input 224 and the audio output 226, with a capacitor (C) 230 connected between the output of the resistor 222 and ground 232. The lowpass filter 220 attenuates high frequency components of the audio input 224, passing low frequency components. The cutoff frequency or knee of the lowpass filter 220 is also calculated as f₀=1/(2*pi*R*C). A resistor 222 of about 1 kΩ and a capacitor 230 of about 0.016 μF results in a 3 dB cutoff frequency of about 10 kHz, filtering out frequency components above about 10,000 Hz.

Referring now to FIG. 9, a simple bandpass filter 240 consists of a highpass filter, made of a capacitor C1 242 and a resistor R1 244, followed by a lowpass filter, made of a resistor R2 246 and a capacitor C2 250. The bandpass filter 240 is connected between the audio input 252 and audio output 254 to filter out high and low frequency components of the audio input 252, passing mid-range frequencies between the cutoff frequencies. The same calculations are used to calculate cutoff frequencies as with the individual highpass and lowpass filters 200 and 220. For example, to pass frequencies between about 200 Hz and about 10 kHz, the following component values may be used: C1 242=0.008 μF, R1 244 =100 kΩ, R2 246=1 kΩ, and C2 250=0.016 μF.

An exemplary combination bandpass filter and amplifier 270 is illustrated in FIG. 10. An audio input 272 is amplified by an operational amplifier 274 with a feedback loop. When the filter portion of the circuit is disabled, the feedback loop consists of an input resistor Ri 276 and a feedback resistor Rf 286. The magnitude of the gain A of the amplifier in this state is calculated as follows: |A|=Rf/Ri. If Rf=50 kΩ and Ri=10 kΩ, |A|=5, amplifying the signal at the input 272 by a factor of five.

A bandpass filter is enabled in the circuit when an output indicator signal 284 is asserted. In the present exemplary embodiment, the bandpass filter is enabled when the active output device is an internal speaker, so the output indicator signal 284 is asserted when the internal speaker is selected.

A lowpass filter is located at the input stage of the circuit to filter out the high frequency components of the input signal 272. The lowpass filter consists of Ri 276 placed in series with the input signal 272, and a capacitor Ci 278 between the output of Ri 276 and ground 282. The lowpass filter is enabled and disabled by a switch 280, such as a field-effect transistor (FET), placed in the path connecting Ci 278 to ground 282. The switch 280 is normally open, disabling the lowpass filter, and is closed when the output indicator signal 284 is asserted, enabling the lowpass filter. The cutoff frequency of the lowpass filter is calculated as 1/(2*pi*Ri*Ci). If Ri is 10 kΩ and Ci is 0.001 μF, the cutoff frequency is about 15.9 kHz.

A highpass filter is located in the feedback loop of the amplifier to filter out the low frequency components of the input signal 272. The highpass filter consists of Rf 286 placed in series in the feedback loop with a capacitor Cf 290. The highpass filter is enabled and disabled by a switch 292 placed in parallel with Cf 290, bypassing Cf 290 when the switch 292 is closed. The switch 292 is normally closed, bypassing Cf 290 to disable the highpass filter. The highpass filter is enabled when the output indicator signal 284 is asserted, opening the switch 292. The cutoff frequency of the highpass filter is calculated as 1/(2*pi*Rf*Cf). If Rf is 50 kΩ and Cf is 0.01 μF, the cutoff frequency is about 318 Hz.

The gain of the bandpass filter and amplifier 270 when the bandpass filter is enabled is calculated as |A|=Zf/Zi, with the DC gain at about zero.

The amplifier 274 may be implemented using an LMV321 operation amplifier, available from the National Semiconductor Corporation of Santa Clara, Calif. The switches 280 and 292 may be implemented using a single NC7SZ66 analog switch, available from Fairchild Semiconductor International of South Portland, Maine.

The audio filters described above have been hardware filters, made of analog electronic circuits. Alternatively, the audio may be filtered in the digital domain by digital electronic circuits, or in a computer processor controlled by firmware. However, as firmware-controlled audio filtering is well known, it will not be described in more detail herein.

As mentioned above, the filters used in the electronic appliance to selectively filter the audio signal based on the output device selection are tailored to produce the best possible sound on the selected output device. The output device properties taken into account include the distortion levels at various frequencies and the frequency response, but may include other properties. For example, the filters may also be used to adjust the tone of the audio signal according to the properties of the output device, if desired. If the internal speaker naturally reproduces high frequency components of an audio signal much better than low and mid-range frequencies, a tinny sound may result. The filter may be used to attenuate high frequency components of the audio signal so that, after amplification, the sound reproduced by the internal speaker has a better tone balance for a full and balanced sound.

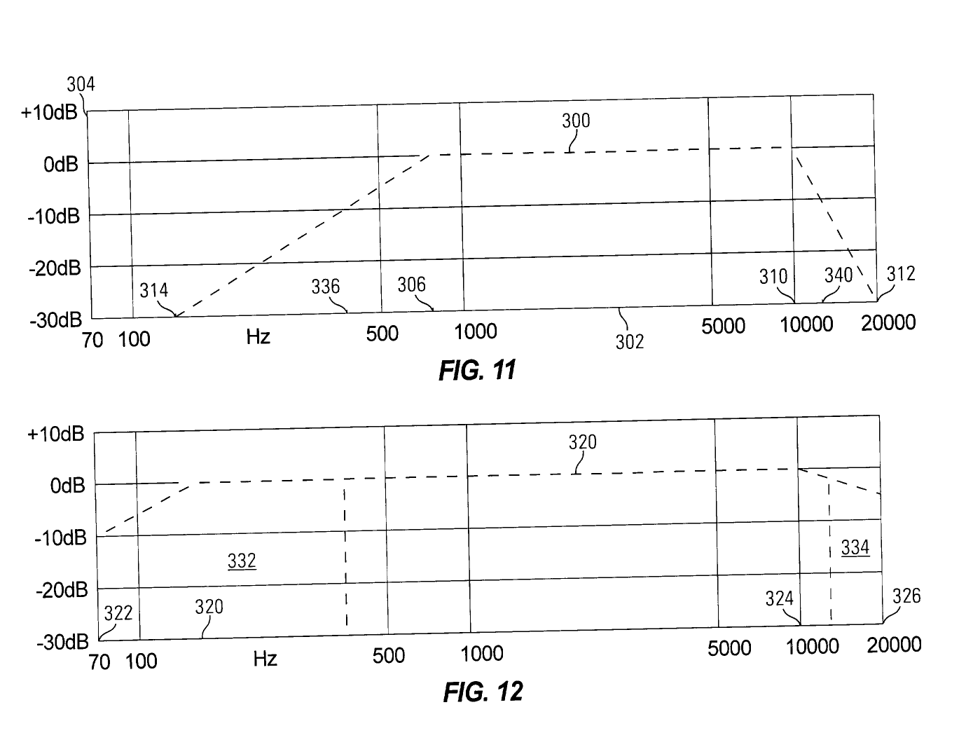

The frequency response of an exemplary small internal speaker 14 is illustrated in the graph of FIG. 11. The dotted line 300 indicates the responsiveness of the internal speaker 14 to the audio signal. The frequency response shown in FIG. 11 has been idealized for simplicity and clarity, resulting in the straight lines and angular cutoff points. The x-axis 302 contains the frequencies of an audio signal arranged along a logarithmic scale, and the y-axis 304 contains a decibel (dB) scale representing the gain or attenuation of the device whose frequency response is shown. A frequency response of 0 dB means that the device does not amplify or attenuate the audio signal, but reproduces it as supplied. A drop in decibels of the frequency response means that the device is not fully responsive to the audio signal and cannot fully reproduce it, effectively attenuating the resulting sound. Each drop of 3 dB means that the sound level has dropped by half.

The exemplary small internal speaker 14 is fully responsive to an audio signal between frequencies of about 750 Hz (306) and about 10 kHz (310). The responsiveness to high frequencies begins dropping off at about 10 kHz (310), reaching −30 dB at about 20 kHz (312). The responsiveness to low frequencies begins dropping off at about 750 Hz (306), reaching −30 dB at about 150 Hz (314). Note that there is no clear frequency at which the speaker 14 can be said to be unresponsive, as the frequency response drops off over a range of frequencies.

The frequency range 320 of an exemplary audio signal (e.g. 102) from an exemplary audio processor (e.g. 100) in an electronic appliance is illustrated in the graph of FIG. 12. This illustrates the gain of the audio processor 100, normalized to 0 dB. Note that the frequency range 320 of the audio signal 102 is wider than the frequency response 300 of the internal speaker 14. The low frequency components of the audio signal 102 begin to fall off at about 175 Hz (320), reaching about −10 dB at 70 Hz (322). The high frequency components of the audio signal 102 begin to fall off at about 10 kHz (324), reaching about −5 dB at 20 kHz (326).

As discussed previously, the filter properties in the electronic appliance are selected according to the output device properties. The speaker 14 may be able to reproduce most of the high frequency components of the audio signal 102, although the frequency response of the speaker falls off more sharply than the high frequency components of the audio signal 102. Thus, in this case the designer may elect to apply a highpass filter rather than a bandpass filter, as much of the distortion in the internal speaker 14 is in the low frequencies. Furthermore, much of the power in the audio signal resides in the low frequencies so not much power is wasted at the high frequency ranges.

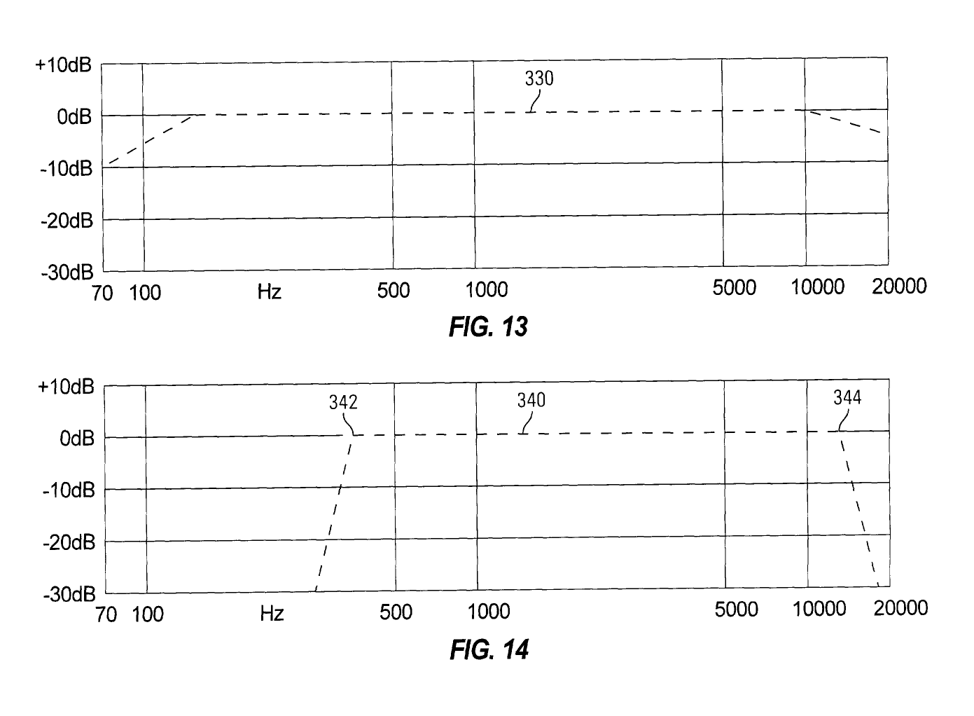

The frequency output (330) of an exemplary optional filter (not shown) and exemplary audio power amplifier (e.g., 132) that may be used for an external output device is shown in the graph of FIG. 13, again normalized to 0 dB. Note that the frequency output of the optional filter and audio power amplifier 132 is matched to the frequency range 320 of the audio signal 102 (shown in FIG. 12), because the external output device is able to substantially reproduce the entire audio signal 102 without distortion. Thus, no filtering is needed to prevent distortion or to reduce wasted power.

In contrast, a great deal of power is wasted if the original audio signal 102 is played by the internal speaker 14, as seen by comparing the frequency response 300 of the speaker 14 (FIG. 11) with the frequency range 320 of the audio signal 302 (FIG. 12). Two regions of wasted power 332 and 334 are illustrated in FIG. 12. These regions 332 and 334 illustrate the portions of the audio signal 102 which are not reproduced well by the internal speaker 14. The points 336 and 340 (FIG. 11) at which the speaker response 300 drops to −12 dB have been somewhat arbitrarily selected as points beyond which the audio signal 302 is wasted.

Perhaps more importantly, considerable distortion may result if the original audio signal 102 is played by the internal speaker 14. A filter may be selectively applied to the audio signal 102 as discussed herein when the internal speaker 14 is the active output device. The frequency output 340 of an exemplary filter is illustrated in the graph of FIG. 14. Note that a knee 342 of the filter is placed at the low frequency point 336 at which the speaker response 300 falls to −12 dB, about 350 Hz, as this was selected as the point at which power is considered wasted. This knee 342 is also selected with the assumption that the portions of the audio signal 102 causing distortion in the speaker 14 are at frequencies lower than this so they will be filtered out as well. Another knee 344 of the filter may be placed at high frequency point 340 at which the speaker response 300 falls to −12 dB, about 12 kHz. However, as the power is already falling off at this point in the audio signal 102, a highpass filter may be used with only the low frequency knee 342 if desired.

The resulting filter is selectively applied to the audio signal 102, removing or attenuating the audio signal 102 in those regions 332 and 334 which cannot be reproduced by the internal speaker 14. This greatly reduces distortion and wasted power.

Again, the filter is designed primarily to prevent distortion in the exemplary embodiment, although minimizing wasted power is also important. The particular design goals for the electronic appliance are taken into account when designing the filter. The filter design may take into many factors, such as the frequencies causing distortion, frequencies which are substantially unreproducible by the output device, and the desire to provide the fullest possible reproducible audio signal to the output device.

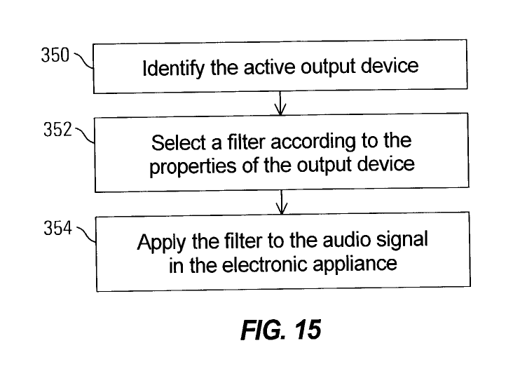

Selective audio filtering in an electronic appliance based on output device selection is summarized in the flowchart of FIG. 15. The active output device is identified 350, and a filter is selected 352 according to the properties of the output device. The filter is applied 354 to the audio signal in the electronic appliance, tailoring the audio signal to the properties of the output device, thereby minimizing distortion and wasted power.

While illustrative embodiments of the invention have been described in detail herein, it is to be understood that the inventive concepts may be otherwise variously embodied and employed, and that the appended claims are intended to be construed to include such variations, except as limited by the prior art.

What is claimed is:

1. A method of outputting an audio signal in an electronic appliance, comprising:
filtering said audio signal for a first output device so that said audio signal comprises a different frequency range for said first output device than for a second output device.

2. The method of claim 1, further comprising:
detecting a destination of said audio signal;
and
selecting a filter in said electronic appliance based on said destination.

3. The method of claim 2, wherein detecting said destination of said audio signal comprises detecting whether said audio signal is connected to a speaker in said electronic appliance.

4. The method of claim 2, wherein detecting said destination of said audio signal comprises detecting whether said audio signal is connected to an output jack in said electronic appliance for transmission to an external device.

5. The method of claim 2, wherein selecting said filter comprises selecting a filter matching a frequency response of said destination.

6. The method of claim 2, wherein selecting said filter comprises selecting a bandpass filter if said destination is an internal speaker in said electronic appliance.

7. The method of claim 2, wherein selecting said filter comprises selecting no filter if said destination is an external device.

8. The method of claim 2, wherein selecting said filter comprises disabling a filter if said destination is an external device.

9. The method of claim 8, wherein disabling said filter comprises switching said audio signal around said filter to bypass said filter.

10. An electronic appliance, comprising:
an audio source;
a plurality of audio output devices connected to said audio source;
at least one audio filter connected between one of said plurality of audio output devices and said audio source, producing a filtered audio signal for said one of said plurality of audio output devices, wherein a frequency range of said filtered audio signal is different than a frequency range of an unfiltered audio signal from said audio source.

11. The electronic appliance of claim 10, further comprising:
at least one signal from at least one of said audio output devices indicating which of said audio output devices are receiving an audio signal from said audio source;
a switch connected to said audio source, said plurality of audio output devices, said at least one audio filter, and said at least one signal, wherein said switch switches said audio source through said at least one audio filter based on which of said audio output devices are receiving said audio signal.

12. The electronic appliance of claim 11, wherein said plurality of audio output devices includes a speaker in said electronic appliance.

13. The electronic appliance of claim 11, wherein said plurality of audio output devices includes an output jack to an external device.

14. The electronic appliance of claim 11, wherein said at least one audio filter comprises a bandpass filter.

15. The electronic appliance of claim 14, wherein a frequency range passed by said bandpass filter is matched to a frequency response of a corresponding one of said plurality of audio output devices connected to said bandpass filter.

16. The electronic appliance of claim 11, wherein said at least one signal causes said switch to switch said audio source through said audio filter to match a frequency range of said audio source to a frequency response of said audio output device which is receiving said audio signal.

17. The electronic appliance of claim 11, said switch comprising a first state in which said audio source is switched through said at least one audio filter and a second state in which said audio source is switched around said at least one audio filter, bypassing said at least one audio filter.

18. The electronic appliance of claim 17, wherein said at least one signal places said switch in said first state when a first of said plurality of audio output devices is receiving said audio signal, and in said second state when a second of said plurality of audio output devices is receiving said audio signal.

19. An electronic appliance, comprising:
means for providing an audio signal in said electronic appliance;
first means for playing said audio signal;
second means for playing said audio signal;
means for determining whether said first means or said second means is playing said audio signal; and
means for filtering said audio signal to match a frequency response of whichever of said first or second means is playing said audio signal.
